(19) United States
(12) Patent Application Publication
(10) Pub. No.: US 2025/0215320 A1
(43) Pub. Date: Jul. 3, 2025

(54) ETCHING METHOD AND PLASMA PROCESSING APPARATUS

(71) Applicant: Tokyo Electron Limited, Tokyo (JP)

(72) Inventors: Ryo MATSUBARA, Miyagi (JP); Yusuke TAKINO, Miyagi (JP); Maju TOMURA, Miyagi (JP)

(73) Assignee: Tokyo Electron Limited, Tokyo (JP)

(21) Appl. No.: 19/062,449

(22) Filed: Feb. 25, 2025

Related U.S. Application Data
(63) Continuation of application No. PCT/JP2023/030184, filed on Aug. 22, 2023.
(60) Provisional application No. 63/373,572, filed on Aug. 26, 2022.

(51) Int. Cl. C09K 13/08; H01J 37/32; H01L 21/3065; H01L 21/308; H01L 21/311

(52) U.S. Cl. CPC C09K 13/08; H01J 37/32449; H01L 21/3065; H01L 21/308; H01L 21/31116; H01L 21/31144; H01J 2237/334

(57) ABSTRACT

A technique of improving an etching shape is provided.

An etching method including: providing a substrate, the substrate including a first film and a second film on the first film, the first film including silicon, and the second film including at least one opening; and forming plasma from a processing gas to etch the first film, the processing gas including a hydrogen fluoride gas, a first halogen-containing gas, and a phosphorus-containing gas, and the first halogen-containing gas containing at least carbon and halogen other than fluorine.

### CROSS-REFERENCE TO RELATED APPLICATIONS

The present application is a continuation of PCT Application No. PCT/JP2023/030184 filed on Aug. 22, 2023, which claims benefit of and hereby incorporates by reference Provisional Patent Application No. 63/373,572 filed on Aug. 26, 2022.

### BACKGROUND

### Field

An exemplary embodiment of the present disclosure relates to an etching method and a plasma processing apparatus.

### Description of Related Art

JP2016-39310A discloses a method of etching a film of a substrate. The film contains silicon. The substrate has a mask provided on the film. The mask includes amorphous carbon or an organic polymer. Plasma formed from a processing gas including a hydrocarbon gas and a fluorohydrocarbon is used for the etching.

### SUMMARY

In one exemplary embodiment of the present disclosure, there is provided an etching method including: providing a substrate, the substrate including a first film and a second film on the first film, the first film including silicon, and the second film including at least one opening; and forming plasma from a processing gas to etch the first film, the processing gas including a hydrogen fluoride gas, a first halogen-containing gas, and a phosphorus-containing gas, and the first halogen-containing gas containing at least carbon and halogen other than fluorine.

### BRIEF DESCRIPTION OF DRAWINGS

FIG. 1 is a diagram for describing a configuration example of a plasma processing system.

FIG. 2 is a diagram for describing a configuration example of a capacitively coupled plasma processing apparatus.

FIG. 3 is a flowchart illustrating a method MT1.

FIG. 4 is a diagram illustrating an example of a cross-sectional structure of a substrate W provided in a step ST11.

FIG. 5 is a diagram illustrating an example of a cross-sectional structure of the substrate W at the end of a step ST12.

FIG. 6 is a diagram for describing examples and a reference example.

### DETAILED DESCRIPTION

Hereinafter, each embodiment of the present disclosure will be described.

In one exemplary embodiment, there is provided an etching method including: providing a substrate, the substrate including a first film and a second film on the first film, the first film including silicon, and the second film including at least one opening; and forming plasma from a processing gas to etch the first film, the processing gas including a hydrogen fluoride gas, a first halogen-containing gas, and a phosphorus-containing gas, and the first halogen-containing gas containing at least carbon and a halogen other than fluorine.

In one exemplary embodiment, the first halogen-containing gas includes a gas represented by CₛHₜBrᵤClᵥF_{w} (s is an integer of 1 or more and 7 or less, a sum of u and v is an integer of 1 or more, and t, u, v, and w are each an integer of 0 or more and 16 or less).

In one exemplary embodiment, the first halogen-containing gas contains bromine as the halogen other than fluorine.

In one exemplary embodiment, the first halogen-containing gas contains chlorine as the halogen other than fluorine.

In one exemplary embodiment, the first halogen-containing gas further contains fluorine.

In one exemplary embodiment, the first halogen-containing gas includes at least one selected from the group consisting of a CHCl₃ gas, a CH₂Cl₂ gas, and a CF₂Br₂Cl₂ gas.

In one exemplary embodiment, the phosphorus-containing gas includes a phosphorus halide gas.

In one exemplary embodiment, the phosphorus-containing gas includes a phosphorus oxyhalide gas.

In one exemplary embodiment, the phosphorus oxyhalide gas includes at least one selected from the group consisting of a POCl₃ gas, a POCl₂F gas, a POClF₂ gas, and a POF₃ gas.

In one exemplary embodiment, the phosphorus-containing gas includes a phosphorus oxyhalide gas and a phosphorus halide gas.

In one exemplary embodiment, a ratio of a partial pressure of the phosphorus halide gas to a partial pressure of the phosphorus oxyhalide gas is 0.1 or more and 3.0 or less.

In one exemplary embodiment, a ratio of flow rates of the phosphorus-containing gas and the first halogen-containing gas to a total flow rate of the processing gas is 20 vol % or less.

In one exemplary embodiment, the processing gas further includes a second halogen-containing gas different from the first halogen-containing gas.

In one exemplary embodiment, the second halogen-containing gas does not contain carbon.

In one exemplary embodiment, the second halogen-containing gas contains a halogen of a type different from the halogen contained in the first halogen-containing gas.

In one exemplary embodiment, the first film includes at least one selected from the group consisting of a silicon oxide film, a silicon nitride film, and a polysilicon film.

In one exemplary embodiment, the second film is a film containing at least any one of carbon and a metal.

In one exemplary embodiment, there is provided an etching method including: providing a substrate, the substrate including a first film and a second film on the first film, the first film including silicon, and the second film including at least one opening; and forming plasma from a processing gas to etch the first film, the processing gas including one or more gases containing fluorine and hydrogen, and capable of generating hydrogen fluoride in the plasma, a first halogen-containing gas, and a phosphorus-containing gas, the first halogen-containing gas containing at least carbon and halogen other than fluorine, and the phosphorus-containing gas containing phosphorus and a halogen.

In one exemplary embodiment, the processing gas further includes a third halogen-containing gas, and the third halogen-containing gas does not contain carbon and phosphorus.

In one exemplary embodiment, there is provided a plasma processing apparatus including: a chamber; and a controller, in which the controller is configured to cause providing a substrate in the chamber, the substrate including a first film and a second film on the first film, the first film including silicon, and the second film including at least one opening, and forming plasma from a processing gas to etch the first film, the processing gas including a hydrogen fluoride gas, a first halogen-containing gas, and a phosphorus-containing gas, and the first halogen-containing gas containing at least carbon and a halogen other than fluorine.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Configuration Example of Plasma Processing System>

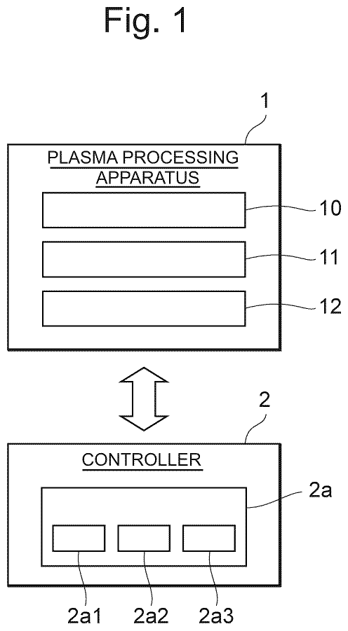

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40, described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, an RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired through a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as a local area network (LAN).

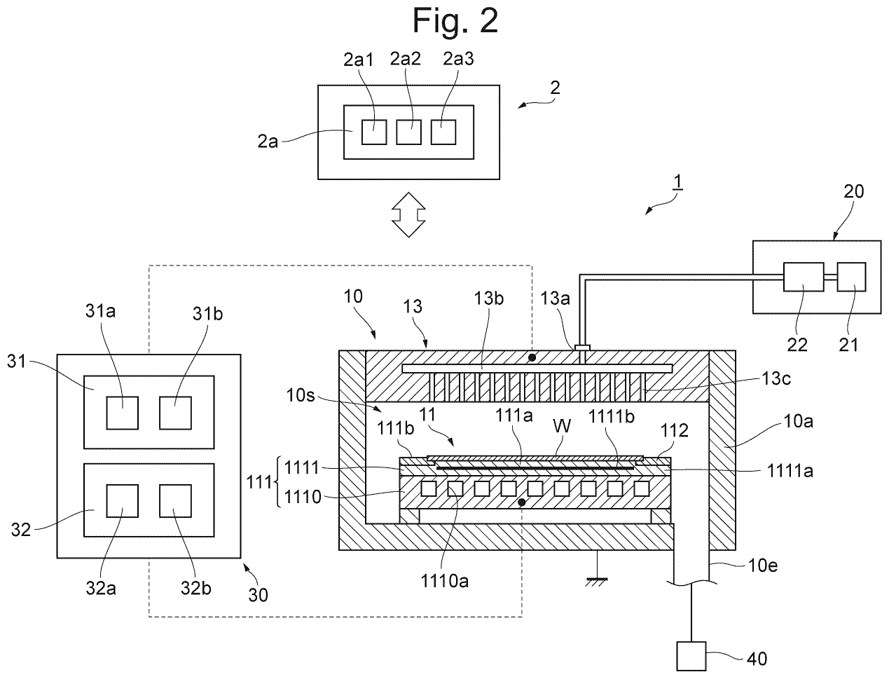

Hereinafter, a configuration example of the capacitively coupled plasma processing apparatus as an example of the plasma processing apparatus 1 will be described. FIG. 2 is a diagram for describing the configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters are disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 through each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in a range of 10 MHz to 150 MHz. In an embodiment, the first RF generator 31a may be configured to generate a plurality of source RF signals having different frequencies. The generated one or plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or plurality of bias RF signals is supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate the first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positively polarized voltage pulses and one or a plurality of negatively-polarized voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### <Example of Plasma Processing Method>

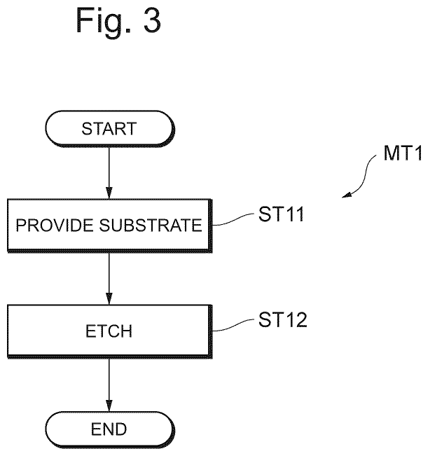

FIG. 3 is a flowchart illustrating an example of a plasma processing method (hereinafter, also referred to as a “method MT1”) according to one exemplary embodiment. As illustrated in FIG. 3, the method MT1 includes a step ST11 of providing the substrate and a step ST12 of performing etching. The processing in each step may be executed by the plasma processing apparatus 1 illustrated in FIGS. 1 and 2. In the following, a case where the controller 2 controls each unit of the plasma processing apparatus 1 illustrated in FIG. 2 to execute the method MT1 will be described as an example.

### (Step ST11: Provision of Substrate)

In the step ST11, the substrate W is provided in the plasma processing chamber 10 (hereinafter, also referred to as a “chamber 10”). In the exemplary embodiment, the substrate W is carried into the chamber 10 by a transport arm, is placed on the substrate support 11 by a lifter, and is suction-held on the substrate support 11 as illustrated in FIG. 2.

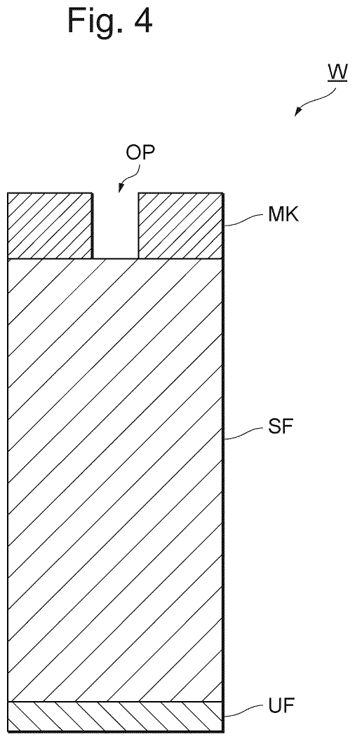

FIG. 4 is a diagram illustrating an example of a cross-sectional structure of the substrate W provided in the step ST11. The substrate W has a silicon-containing film SF and a mask MK disposed on the silicon-containing film SF. The silicon-containing film SF may be formed on an underlying film UF. The substrate W may be used for manufacturing a semiconductor device. The semiconductor device includes, for example, a memory device such as a DRAM or a 3D-NAND flash memory, and a logic device.

In the exemplary embodiment, the underlying film UF is a silicon wafer, an organic film, a dielectric film, a metal film, a semiconductor film, or the like formed on the silicon wafer. In the exemplary embodiment, the underlying film UF may be configured by stacking a plurality of films.

The silicon-containing film SF is a film to be subjected to etching by the method MT1. The silicon-containing film SF is an example of a first film. In the exemplary embodiment, the silicon-containing film SF may be a silicon oxide film, a silicon nitride film, a silicon carbonitride film, a polycrystalline silicon film, or a carbon-containing silicon film. In the exemplary embodiment, the silicon-containing film SF may be configured by stacking two or more of one or a plurality of types of films. For example, the silicon-containing film SF may be configured by alternately stacking the silicon oxide film and the silicon nitride film. For example, the silicon-containing film SF may be configured by alternately stacking the silicon oxide film and the polycrystalline silicon film. For example, the silicon-containing film SF may be a film stack including the silicon nitride film, the silicon oxide film, and the polycrystalline silicon film. For example, the silicon-containing film SF may be configured by stacking the silicon oxide film and the silicon carbonitride film. For example, the silicon-containing film SF may be a film stack including the silicon oxide film, the silicon nitride film, and the silicon carbonitride film. In the exemplary embodiment, the silicon-containing film SF may be doped with an element such as phosphorus, boron, or nitrogen.

The mask MK is formed on the silicon-containing film SF. The mask MK is an example of a second film. The mask MK has at least one opening OP. The opening OP is a space on the silicon-containing film SF and is surrounded by a side wall of the mask MK. That is, an upper surface of the silicon-containing film SF has a region covered by the mask MK and a region exposed at a bottom portion of the opening OP. The opening OP may be a hole or a slit.

In the exemplary embodiment, the mask MK may be a carbon-containing film. The carbon-containing film includes, for example, at least one selected from the group consisting of a spin-on carbon (SOC) film, tungsten carbide, an amorphous carbon (ACL) film, a boron carbide film, and a photoresist film. In an example, the ACL film may be doped with elements such as boron, arsenic, tungsten, and xenon.

In the exemplary embodiment, the mask MK may be a metal-containing film. The metal-containing film contains at least one metal selected from the group consisting of tungsten, molybdenum, ruthenium, and titanium. The metal-containing film may contain, for example, a carbide or a silicide of tungsten, molybdenum, or titanium. The metal-containing film may be, for example, a tungsten-containing film. The metal-containing film may further contain at least one selected from the group consisting of tungsten, silicon, carbon, and nitrogen. In an example, the metal-containing film contains at least one selected from the group consisting of tungsten carbide (WC), tungsten silicide (WSi), WSiN, and WSiC. The mask MK may be a single-layer mask consisting of one layer, or may be a multilayer mask consisting of two or more layers.

Each of the underlying film UF, the silicon-containing film SF, and the mask MK may be formed by any method. For example, each of the underlying film UF, the silicon-containing film SF, and the mask MK may be formed by a CVD method, an ALD method, a PVD method, a spin coating method, or the like. The mask MK may be formed by, for example, lithography. Further, the opening OP of the mask MK may be formed by etching the mask MK. Each of the underlying film UF, the silicon-containing film SF, and the mask MK may be a flat film or a film including unevenness. The substrate W may further include another film under the underlying film UF. In this case, a concave portion having a shape corresponding to the opening OP may be formed in the silicon-containing film SF and the underlying film UF, and used as a mask for etching the other films.

In the exemplary embodiment, at least a part of the process of forming the underlying film UF, the silicon-containing film SF, and the mask MK on the substrate W may be performed in the chamber 10 as a part of the step ST11. For example, in a case where the opening OP of the mask MK is formed by etching, the etching in the step ST11 and the etching in the step ST12 described later may be continuously executed in the chamber 10. In the exemplary embodiment, after all or a part of the substrate W is formed by an external device or a chamber of the plasma processing apparatus 1, the substrate W may be provided in the chamber 10.

In the exemplary embodiment, after the substrate W is provided in the center region 111a of the substrate support 11, the substrate support 11 is controlled to a set temperature by the temperature-controlled module. The set temperature may be, for example, a normal temperature (for example, 25° C.) or lower, 0° C. or lower, −10° C. or lower, −20° C. or lower, −30° C. or lower, −40° C. or lower, −50° C. or lower, −60° C. or lower, or −70° C. or lower. The set temperature may be, for example, −100° C. or higher or −90° C. or higher.

In the exemplary embodiment, controlling the temperature of the substrate support 11 to the set temperature includes setting the temperature of the heat transfer fluid flowing through the flow passage 1110a and the heater temperature to the set temperature or a temperature different from the set temperature. Timing at which the heat transfer fluid starts to flow through the flow passage 1110a may be before or after the substrate W is placed on the substrate support 11, or may be at the same time. In addition, the temperature of the substrate support 11 may be controlled to a set temperature before the step ST11. That is, the substrate W may be provided on the substrate support 11 after the temperature of the substrate support 11 is controlled to the set temperature.

In the exemplary embodiment, the substrate W may be controlled to the set temperature instead of controlling the substrate support 11 to the set temperature. Controlling the temperature of the substrate W to the set temperature includes setting the temperature of the substrate support 11, the temperature of the heat transfer fluid flowing through the flow passage 1110a, and/or the heater temperature to the set temperature or to a temperature different from the set temperature.

### (Step ST12: Etching)

In the step ST12, the silicon-containing film SF is etched using the plasma formed from the processing gas. First, the processing gas is supplied into the plasma processing space 10s from the gas supply 20. The processing gas includes a hydrogen fluoride (HF) gas, a phosphorus-containing gas, and a first halogen-containing gas.

In the exemplary embodiment, the HF gas may have the highest flow rate (partial pressure) in the processing gas excluding the inert gas. In an example, the flow rate of the HF gas may be 50 vol % or more, 60 vol % or more, 70 vol % or more, 80 vol % or more, 90 vol % or more, or 95 vol % or more with respect to the total flow rate of the processing gas (the flow rate of all gases excluding these gases in a case where the processing gas includes an inert gas). The flow rate of the HF gas may be less than 100 vol %, 99.5 vol % or less, 98 vol % or less, or 96 vol % or less with respect to the total flow rate of the processing gas. In an example, the flow rate of the HF gas is 70 vol % or more and 96 vol % or less with respect to the total flow rate of the processing gas.

In the exemplary embodiment, the processing gas may include a gas capable of generating a hydrogen fluoride species (HF species) in the plasma, instead of a part or all of the HF gas. The HF species includes at least one of a gas of hydrogen fluoride, a radical, or an ion.

The gas capable of generating an HF species may be, for example, a hydrofluorocarbon gas. The hydrofluorocarbon gas may have 2 or more carbon atoms, 3 or more carbon atoms, or 4 or more carbon atoms. In an example, the hydrofluorocarbon gas is at least one selected from the group consisting of CH₂F₂ gas, C₃H₂F₄ gas, C₃H₂F₆ gas, C₃H₃F₅ gas, C₄H₂F₆ gas, C₄HF₅ gas, C₄H₂F₈ gas, C₅H₂F₆ gas, C₅H₂F₁₀ gas, and C₅H₃F₇ gas. In an example, the hydrofluorocarbon gas is at least one selected from the group consisting of CH₂F₂ gas, C₃H₂F₄ gas, C₃H₂F₆ gas, and C₄H₂F₆ gas.

The gas capable of generating the HF species may be, for example, a mixed gas including a hydrogen source and a fluorine source. The hydrogen source may be, for example, at least one selected from the group consisting of H₂ gas, NH₃ gas, H₂O gas, H₂O₂ gas, and hydrocarbon gas (CH₄ gas, C₃H₆ gas, and the like). The fluorine source may be, for example, a fluorine-containing gas that does not include carbon, such as NF₃ gas, SF₆ gas, WF₆ gas, or XeF₂ gas. In addition, the fluorine source may be a fluorine-containing gas containing carbon, such as fluorocarbon gas and hydrofluorocarbon gas. In an example, the fluorocarbon gases may be at least one selected from the group consisting of CF₄ gas, C₂F₂ gas, C₂F₄ gas, C₃F₆ gas, C₃F₈ gas, C₄F₆ gas, C₄F₈ gas, and CSFs gas. In an example, the hydrofluorocarbon gas may be at least one selected from the group consisting of CHF₃ gas, CH₂F₂ gas, CH₃F gas, C₂HF₅ gas, and a hydrofluorocarbon gas containing three or more of C (C₃H₂F₄ gas, C₃H₂F₆ gas, C₄H₂F₆ gas, and the like).

In the exemplary embodiment, the phosphorus-containing gas may include a phosphorus oxyhalide gas. In an embodiment, the phosphorus oxyhalide gas may be a gas represented by POClₓF_{y} (here, 0≤x≤3, 0≤y≤3, and x+y=3). For example, the phosphorus oxyhalide gas may be at least one selected from the group consisting of a POCl₃ gas, a POCl₂F gas, a POClF₂ gas, and a POF₃ gas. In an example, the phosphorus oxyhalide gas may be a POCl₃ gas or a POF₃ gas.

In the exemplary embodiment, the phosphorus-containing gas may include the phosphorus halide gas in addition to the above-described phosphorus oxyhalide gas. In the exemplary embodiment, the phosphorus halide gas is a gas containing phosphorus, fluorine, and/or chlorine, and not containing oxygen. For example, the phosphorus halide gas may be at least one selected from the group consisting of PF₃ gas, PF₅ gas, PCl₃ gas, PCl₅ gas, PClF₂ gas, PCl₂F gas, and PCl₂F₃. In an example, the phosphorus halide gas may be a PF₃ gas, a PF₅ gas, or a PCl₃ gas.

In the exemplary embodiment, in a case where the phosphorus-containing gas includes a phosphorus oxyhalide gas and a phosphorus halide gas, a ratio of a flow rate (partial pressure) of the phosphorus halide gas to a flow rate (partial pressure) of the phosphorus oxyhalide gas may be 0.1 or more, 0.2 or more, or 0.3 or more. In addition, the ratio of the flow rate (partial pressure) of the phosphorus halide gas to the flow rate (partial pressure) of the phosphorus oxyhalide gas may be 3.0 or less, 2.0 or less, or 1.0 or less. In an example, the ratio of the flow rate (partial pressure) of the phosphorus halide gas to the flow rate (partial pressure) of the phosphorus oxyhalide gas is 0.2 or more and 3.0 or less. By controlling the flow rate (partial pressure) of the phosphorus halide gas with respect to the flow rate (partial pressure) of the phosphorus oxyhalide gas to be within the above-described range, it is possible to suppress an abnormality in an etching shape such as bowing.

In the exemplary embodiment, the first halogen-containing gas is a gas containing at least carbon and halogen other than fluorine. The halogen other than fluorine may be at least one selected from the group consisting of bromine (Br), chlorine (Cl), and iodine (I). The halogen other than fluorine may include a halogen of a type different from the halogen contained in the phosphorus-containing gas in a case where the phosphorus-containing gas contains the halogen.

In the exemplary embodiment, the first halogen-containing gas may be a gas represented by CₛHₜBrᵤClᵥF_{w} (s is an integer of 1 or more and 7 or less, a sum of u and v is an integer of 1 or more, and t, u, v, and w are each an integer of 0 or more and 16 or less). For example, the first halogen-containing gas may be a gas in which a part or all of hydrogen atoms of methane (CH₄) are substituted with bromine. For example, the first halogen-containing gas may be a gas in which a part or all of hydrogen atoms of methane (CH₄) are substituted with bromine and a halogen other than bromine. That is, in the above-described chemical formula, s=1 and t+u+v+w=4 may be satisfied. In an example, the first halogen-containing gas may be at least one gas selected from the group consisting of a CH₃Br gas, a CH₂BrF gas, a CBr₂F₂ gas, a CBr₂ClF gas, and a CHBrCl₂ gas.

In addition, for example, the first halogen-containing gas may be at least one selected from the group consisting of a CCl₄ gas, a CH₂Cl₂ gas, a CHCl₃ gas, a CF₂Cl₂ gas, a CH₂ClF gas, a CHCl₂F gas, a C₂F₅Br gas, a CF₃I gas, a C₂F₅I gas, and a C₃F₇I gas.

In the exemplary embodiment, the ratio of the flow rate (partial pressure) of the first halogen-containing gas to the flow rate (partial pressure) of the phosphorus-containing gas may be appropriately set depending on the film type of the silicon-containing film SF, the flow rate (partial pressure) of the HF gas, the type and atomic ratio of the halogen contained in the phosphorus-containing gas and the first halogen-containing gas, the shape to be a target, and the like. In the exemplary embodiment, the ratio of the flow rate (partial pressure) of the first halogen-containing gas to the flow rate (partial pressure) of the phosphorus-containing gas may be 0.1 or more, 0.2 or more, or 0.3 or more. In addition, the ratio of the flow rate (partial pressure) of the first halogen-containing gas to the flow rate (partial pressure) of the phosphorus-containing gas may be 1.5 or less, 1.2 or less, or 1.0 or less. The ratio of the flow rate (partial pressure) of the halogen-containing gas to the flow rate (partial pressure) of the phosphorus-containing gas is, in an example, 0.1 or more and 1.5 or less.

In the exemplary embodiment, the ratio of the total flow rate of the phosphorus-containing gas and the first halogen-containing gas to the total flow rate of the processing gas (total flow rate of all gases excluding the inert gas in a case where the processing gas includes the inert gas) may be controlled to 20 vol % or less, 15 vol % or less, or 10 vol % or less.

In the exemplary embodiment, the processing gas may include a gas other than the HF gas, the phosphorus-containing gas, and the first halogen-containing gas. For example, the processing gas may further include at least one gas selected from the group consisting of a second halogen-containing gas, a carbon-containing gas, a tungsten-containing gas, and an oxygen-containing gas.

The second halogen-containing gas is a gas different from the first halogen-containing gas. For example, the second halogen-containing gas contains a halogen other than the halogen contained in the first halogen-containing gas. For example, in a case where the first halogen-containing gas contains bromine (Br) and does not contain chlorine (Cl), the second halogen-containing gas may contain at least chlorine (Cl). In addition, for example, in a case where the first halogen-containing gas contains chlorine (Cl) and does not contain bromine (Br), the second halogen-containing gas may contain at least bromine (Br). In the exemplary embodiment, at least one of the first halogen-containing gas or the second halogen-containing gas may contain chlorine (Cl). In the exemplary embodiment, at least one of the first halogen-containing gas and the second halogen-containing gas may contain bromine (Br).

In addition, for example, the second halogen-containing gas may contain a halogen other than fluorine. For example, the second halogen-containing gas may be a chlorine-containing gas, a bromine-containing gas, and/or an iodine-containing gas. In an example, the chlorine-containing gas may be at least one gas selected from the group consisting of Cl₂, SiCl₂, SiC₄, CCl₄, SiH₂Cl₂, Si₂Cl₆, CHCl₃, SO₂Cl₂, BCl₃, PCl₃, PCl₅, and POCl₃. In an example, the bromine-containing gas may be at least one gas selected from the group consisting of Br₂, HBr, CBr₂F₂, C₂F₅Br, PBr₃, PBr₅, POBr₃, and BBr₃. In an example, the iodine-containing gas may be at least one gas selected from the group consisting of HI, CF₃I, C₂F₅I, C₃F₇I, IF₅, IF₇, I₂, and PI₃. In an example, the second halogen-containing gas may be at least one selected from the group consisting of a Cl₂ gas, a Br₂ gas, and an HBr gas. In an example, the second halogen-containing gas is a Cl₂ gas or an HBr gas.

The carbon-containing gas may be, for example, either or both of the fluorocarbon gas and the hydrofluorocarbon gas. In an example, the fluorocarbon gas may be at least one selected from the group consisting of CF₄ gas, C₂F₂ gas, C₂F₄ gas, C₃F₆ gas, C₃F₈ gas, C₄F₆ gas, C₄F₈ gas, and CSFs gas. In an example, the hydrofluorocarbon gas may be at least one selected from the group consisting of CHF₃ gas, CH₂F₂ gas, CH₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In addition, the carbon-containing gas may be a linear one having an unsaturated bond. The linear carbon-containing gas having the unsaturated bond may be, for example, at least one selected from the group consisting of hexafluoropropene (C₃F₆) gas, octafluoro-1-butene, octafluoro-2-butene (C₄F₈) gas, 1,3,3,3-tetrafluoropropene (C₃H₂F₄) gas, trans-1,1,1,4,4,4-hexafluoro-2-butene (C₄H₂F₆) gas, pentafluoroethyl trifluorovinyl ether (C₄F₈O) gas, CF₃COF gas (1,2,2,2-tetrafluoroethane-1-one), difluoroacetic acid fluoride (CHF₂COF) gas, and carbonyl fluoride (COF₂) gas.

The tungsten-containing gas may be, for example, a gas containing tungsten and a halogen. Specifically, the tungsten-containing gas may be a gas containing tungsten and fluorine such as tungsten difluoride (WF₂) gas, tungsten tetrafluoride (WF₄) gas, tungsten pentafluoride (WF₅) gas, and tungsten hexafluoride (WF₆) gas, and a gas containing tungsten and chlorine such as tungsten dichloride (WCl₂) gas, tungsten tetrachloride (WCl₄) gas, tungsten pentachloride (WCl₅) gas, and tungsten hexachloride (WCl₆) gas. Among these, at least one gas of WF₆ gas and WCl₆ gas may be used. The flow rate of the tungsten-containing gas may be 5 vol % or less of the total flow rate of the processing gas. The processing gas may include at least one of a titanium-containing gas, a ruthenium-containing gas, and/or a molybdenum-containing gas, instead of or in addition to the tungsten-containing gas.

The oxygen-containing gas may be, for example, at least one gas selected from the group consisting of O₂, CO, CO₂, H₂O, and H₂O₂. In an example, the oxygen-containing gas may be an oxygen-containing gas other than H₂O, for example, at least one gas selected from the group consisting of O₂, CO, CO₂, and H₂O₂.

In the exemplary embodiment, the processing gas may further include an inert gas. In an example, the inert gas may be a noble gas such as Ar gas, He gas, and Kr gas, or nitrogen gas.

During the processing in the step ST12, the gas included in the processing gas and the flow rate (partial pressure) thereof may or may not be changed. For example, in a case where the silicon-containing film SF is formed of a film stack consisting of a silicon-containing film which is a type different from the silicon-containing film SF, the configuration of the processing gas and the flow rate (partial pressure) of each gas may be changed according to the progress of etching (that is, according to the type of film to be etched). During the processing in the step ST12, the temperature of the substrate support 11 may be maintained at the set temperature adjusted in the step ST11, or may be changed.

In the step ST12, after the above-described processing gas is supplied into the plasma processing space 10s, plasma is formed from the processing gas. As a result, the substrate W is etched. In the exemplary embodiment, the formation of plasma may be executed as follows. First, the source RF signal is supplied to the lower electrode of the substrate support 11 and/or at least one upper electrode of the shower head 13. As a result, an RF electric field is generated between the shower head 13 and the substrate support 11, and plasma is formed from the processing gas in the chamber 10. In addition, a bias signal is supplied to the lower electrode of the substrate support 11. As a result, the active species in the plasma are attracted to the substrate W, and the silicon-containing film SF is etched.

In the exemplary embodiment, the bias signal may be the bias RF signal supplied from the second RF generator 31b. In addition, the bias signal may be the bias DC signal supplied from the DC generator 32a. Both of the source RF signal and the bias signal may be the continuous wave or the pulse wave, and one may be the continuous wave and the other may be the pulse wave. In a case where both of the source RF signal and the bias signal are the pulse waves, cycles of both pulse waves may or may not be synchronized. A duty ratio of the pulse wave of the source RF signal and/or the bias signal may be appropriately set, and may be, for example, 1 to 80% and 5 to 50%. The duty ratio is a ratio occupied by a period in which power or a voltage level is high in the cycle of the pulse wave. In addition, in a case where the bias DC signal is used as the bias signal, the pulse wave may have a rectangular shape, a trapezoidal shape, a triangular shape, or a waveform of a combination thereof. The polarity of the bias DC signal may be negative or positive as long as the potential of the substrate W is set to give a potential difference between plasma and the substrate to draw ions.

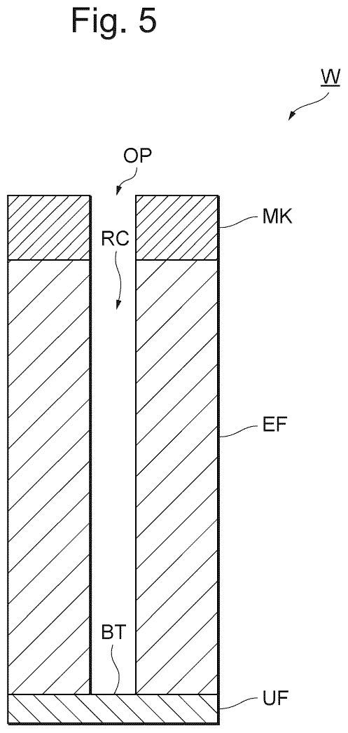

FIG. 5 is a diagram illustrating an example of a cross-sectional structure of the substrate W at the end of the step ST12. As illustrated in FIG. 5, an exposed portion of the silicon-containing film SF at the opening OP is etched in a depth direction (direction from top to bottom in FIG. 5), and the concave portion RC is formed by the processing in the step ST12. FIG. 5 illustrates an example in which the bottom portion BT of the concave portion RC reaches the underlying film UF and the underlying film UF is exposed by the etching in the step ST12. The aspect ratio of the concave portion RC in this state may be, for example, 20 or more, 30 or more, 40 or more, 50 or more, or 100 or more.

As described above, the processing gas includes an HF gas, a phosphorus-containing gas, and a first halogen-containing gas. The HF gas generates HF species in plasma and functions as an etchant of the silicon-containing film SF. The phosphorus-containing gas promotes a reaction between the HF species and the silicon-containing film SF. In a case where the phosphorus-containing gas is the phosphorus oxyhalide gas and/or the phosphorus halide gas, such a phosphorus-containing gas may contribute to improvement of etching shape and suppression of blocking (clogging) of the opening OP while promoting the reaction between the HF species and the silicon-containing film SF. In addition, the first halogen-containing gas contributes to improvement of the etching shape and protection of the mask MK. The improvement of the etching shape may be improvement of roundness, suppression of bending, and/or suppression of bowing.

The first halogen-containing gas or the phosphorus-containing gas (phosphorus oxyhalide gas and/or phosphorus halide gas) is a gas having a plurality of functions in etching as described above. Since these gases are gases consisting of one molecule, the partial pressure in the processing gas can be suppressed to be lower than that in a case where two or more different gases are combined in order to obtain the same function. As a result, the partial pressure of the HF gas, which is the etchant in the processing gas, can be increased. Therefore, according to the method MT1, it is possible to realize improvement of the etching shape, suppression of clogging, or protection of the mask while maintaining the partial pressure of the HF gas at a high level.

According to one exemplary embodiment of the present disclosure, it is possible to provide a technique for improving an etching shape.

### EXAMPLES

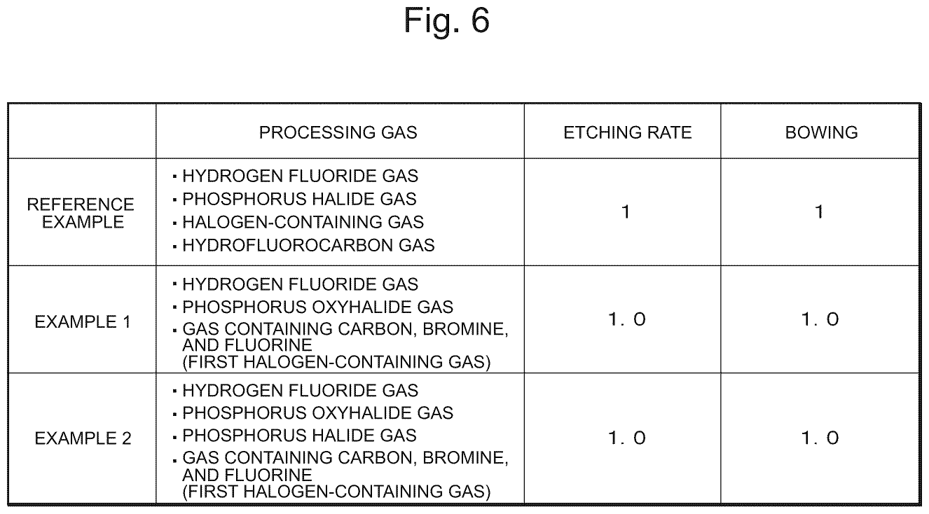

Next, examples will be described. The present disclosure is not limited in any way by following examples. FIG. 6 is a diagram for describing examples and a reference example.

### Example 1

The substrate W illustrated in FIG. 4 was etched along the flowchart described in FIG. 3 using the plasma processing apparatus 1 illustrated in FIG. 2. First, in the step ST11, the substrate W was provided on the substrate support 11. The silicon-containing film SF of the substrate W was a multilayered film stack consisting of the silicon oxide film and the silicon nitride film. The mask MK was an amorphous carbon film having the hole-shaped opening OP. Subsequently, in the step ST12, the silicon-containing film SF was etched using the formed plasma that is formed from the processing gas illustrated in the column of “Example 1” in FIG. 6.

### Example 2

Example 2 is the same as Example 1 except that in the step ST12, the processing gas illustrated in the column of “Example 2” in FIG. 6 is used.

### Reference Example

The reference example is the same as Example 1 except that in the step ST12, the processing gas illustrated in the column of the “reference example” in FIG. 6 is used.

In FIG. 6, the “etching rate” is an etching rate of each example in a case where the etching rate of the reference example is set to 1. In addition, the “bowing” indicates the critical dimension (CD) of the bowing generated in the silicon-containing film SF of each example in a case where the CD of the bowing generated in the silicon-containing film SF of the reference example is set to 1. As illustrated in FIG. 6, in both of Example 1 and Example 2, the etching rate similar to that of the reference example could be achieved. In addition, the bowing in the both of Example 1 and Example 2 could be suppressed similar to that of the reference example.

According to one exemplary embodiment of the present disclosure, it is possible to provide a technique for improving an etching shape.

The embodiments of the present disclosure further include the following aspects.

### (Addendum 1)

An etching method including:
providing a substrate, the substrate including a first film and a second film on the first film, the first film including silicon, and the second film including at least one opening; and
forming plasma from a processing gas to etch the first film, the processing gas including a hydrogen fluoride gas, a first halogen-containing gas, and a phosphorus-containing gas, and the first halogen-containing gas containing at least a halogen other than carbon and fluorine.

### (Addendum 2)

The etching method according to Addendum 1, in which the first halogen-containing gas includes a gas represented by CₛHₜBrᵤClᵥF_{w} (s is an integer of 1 or more and 7 or less, a sum of u and v is an integer of 1 or more, and t, u, v, and w are each an integer of 0 or more and 16 or less).

### (Addendum 3)

The etching method according to Addendum 1 or 2, in which the first halogen-containing gas contains bromine as the halogen other than fluorine.

### (Addendum 4)

The etching method according to any one of Addenda 1 to 3, in which the first halogen-containing gas contains chlorine as the halogen other than fluorine.

### (Addendum 5)

The etching method according to any one of Addenda 1 to 4, in which the first halogen-containing gas further contains fluorine.

### (Addendum 6)

The etching method according to any one of Addenda 1 to 5, in which the first halogen-containing gas includes at least one selected from the group consisting of a CHCl₃ gas, a CH₂Cl₂ gas, and a CF₂Br₂Cl₂ gas.

### (Addendum 7)

The etching method according to any one of Addenda 1 to 6, in which the phosphorus-containing gas includes a phosphorus halide gas.

### (Addendum 8)

The etching method according to any one of Addenda 1 to 7, in which the phosphorus-containing gas includes a phosphorus oxyhalide gas.

### (Addendum 9)

The etching method according to Addendum 8, in which the phosphorus oxyhalide gas includes at least one selected from the group consisting of a POCl₃ gas, a POCl₂F gas, a POClF₂ gas, and a POF₃ gas.

### (Addendum 10)

The etching method according to any one of Addenda 1 to 9, in which the phosphorus-containing gas includes a phosphorus oxyhalide gas and a phosphorus halide gas.

### (Addendum 11)

The etching method according to Addendum 10, in which a ratio of a partial pressure of the phosphorus halide gas to a partial pressure of the phosphorus oxyhalide gas is 0.1 or more and 3.0 or less.

### (Addendum 12)

The etching method according to any one of Addenda 1 to 11, in which a ratio of flow rates of the phosphorus-containing gas and the first halogen-containing gas to a total flow rate of the processing gas is 20 vol % or less.

### (Addendum 13)

The etching method according to any one of Addenda 1 to 12, in which the processing gas further includes a second halogen-containing gas different from the first halogen-containing gas.

### (Addendum 14)

The etching method as described in Addendum 13, in which the second halogen-containing gas does not contain carbon.

### (Addendum 15)

The etching method according to Addendum 13 or 14, in which the second halogen-containing gas contains a halogen of a type different from the halogen contained in the first halogen-containing gas.

### (Addendum 16)

The etching method according to any one of Addenda 1 to 15, in which the first film includes at least one selected from the group consisting of a silicon oxide film, a silicon nitride film, and a polysilicon film.

### (Addendum 17)

The etching method according to any one of Addenda 1 to 16, in which the second film is a film containing at least any one of carbon and a metal.

### (Addendum 18)

An etching method including:
providing a substrate, the substrate including a first film and a second film on the first film, the first film including silicon, and the second film including at least one opening; and
forming plasma from a processing gas to etch the first film, the processing gas including one or more gases containing fluorine and hydrogen, and capable of generating hydrogen fluoride in the plasma, a first halogen-containing gas, and a phosphorus-containing gas, the first halogen-containing gas containing at least a halogen other than carbon and fluorine, and the phosphorus-containing gas containing phosphorus and a halogen.

### (Addendum 19)

The etching method according to Addendum 18, in which the processing gas further includes a third halogen-containing gas, and the third halogen-containing gas does not contain carbon and phosphorus.

### (Addendum 20)

A plasma processing apparatus including:
a chamber; and
a controller, in which
the controller is configured to cause
providing a substrate in the chamber, the substrate including a first film and a second film on the first film, the first film including silicon, and the second film including at least one opening, and
forming plasma from a processing gas to etch the first film, the processing gas including a hydrogen fluoride gas, a first halogen-containing gas, and a phosphorus-containing gas, and the first halogen-containing gas containing at least a halogen other than carbon and fluorine.

Each of the above-described embodiments is described for the purpose of description, and is not intended to limit the scope of the present disclosure. Each of the above-described embodiments may be modified in various ways without departing from the scope and gist of the present disclosure. For example, some configuration elements in one embodiment can be added to another embodiment. In addition, some configuration elements in one embodiment are able to be replaced with corresponding configuration elements in another embodiment.

What is claimed is:

1. An etching method comprising:
providing a substrate, the substrate including a first film and a second film on the first film, the first film including silicon, and the second film including at least one opening; and
forming plasma from a processing gas to etch the first film, the processing gas including a hydrogen fluoride gas, a first halogen-containing gas, and a phosphorus-containing gas, and the first halogen-containing gas containing at least carbon and halogen other than fluorine.

2. The etching method according to claim 1, wherein the first halogen-containing gas includes a gas represented by CₛHₜBrᵤClᵥF_{w} (s is an integer of 1 or more and 7 or less, a sum of u and v is an integer of 1 or more, and t, u, v, and w are each an integer of 0 or more and 16 or less).

3. The etching method according to claim 1, wherein the first halogen-containing gas contains bromine as the halogen other than fluorine.

4. The etching method according to claim 1, wherein the first halogen-containing gas contains chlorine as the halogen other than fluorine.

5. The etching method according to claim 1, wherein the first halogen-containing gas further contains fluorine.

6. The etching method according to claim 1, wherein the first halogen-containing gas includes at least one selected from the group consisting of a CHCl₃ gas, a CH₂Cl₂ gas, and a CF₂Br₂Cl₂ gas.

7. The etching method according to claim 1, wherein the phosphorus-containing gas includes a phosphorus halide gas.

8. The etching method according to claim 1, wherein the phosphorus-containing gas includes a phosphorus oxyhalide gas.

9. The etching method according to claim 8, wherein the phosphorus oxyhalide gas includes at least one selected from the group consisting of a POCl₃ gas, a POCl₂F gas, a POClF₂ gas, and a POF₃ gas.

10. The etching method according to claim 1, wherein the phosphorus-containing gas includes a phosphorus oxyhalide gas and a phosphorus halide gas.

11. The etching method according to claim 10, wherein a ratio of a partial pressure of the phosphorus halide gas to a partial pressure of the phosphorus oxyhalide gas is 0.1 or more and 3.0 or less.

12. The etching method according to claim 1, wherein a ratio of flow rates of the phosphorus-containing gas and the first halogen-containing gas to a total flow rate of the processing gas is 20 vol % or less.

13. The etching method according to claim 1, wherein the processing gas further includes a second halogen-containing gas different from the first halogen-containing gas.

14. The etching method according to claim 13, wherein the second halogen-containing gas does not contain carbon.

15. The etching method according to claim 13, wherein the second halogen-containing gas contains a halogen of a type different from the halogen contained in the first halogen-containing gas.

16. The etching method according to claim 1, wherein the first film includes at least one selected from the group consisting of a silicon oxide film, a silicon nitride film, and a polysilicon film.

17. The etching method according to claim 1, wherein the second film is a film containing at least any one of carbon and a metal.

18. An etching method comprising:
providing a substrate, the substrate including a first film and a second film on the first film, the first film including silicon, and the second film including at least one opening; and
forming plasma from a processing gas to etch the first film, the processing gas including one or more gases containing fluorine and hydrogen, and capable of generating hydrogen fluoride in the plasma, a first halogen-containing gas, and a phosphorus-containing gas, the first halogen-containing gas containing at least carbon and halogen other than fluorine, and the phosphorus-containing gas containing phosphorus and a halogen.

19. The etching method according to claim 18, wherein the processing gas further includes a third halogen-containing gas, and the third halogen-containing gas does not contain carbon and phosphorus.

20. A plasma processing apparatus comprising:
a chamber; and
a controller, wherein
the controller is configured to cause
providing a substrate in the chamber, the substrate including a first film and a second film on the first film, the first film including silicon, and the second film including at least one opening, and
forming plasma from a processing gas to etch the first film, the processing gas including a hydrogen fluoride gas, a first halogen-containing gas, and a phosphorus-containing gas, and the first halogen-containing gas containing at least carbon and a halogen other than fluorine.
